(19) United States
(12) Patent Application Publication
(10) Pub. No.: US 2015/0359141 A1
(43) Pub. Date: Dec. 10, 2015

(54) LIQUID-COOLED JACKET AND ELECTRONIC DEVICE

(71) Applicant: FUJITSU LIMITED, Kawasaki-shi (JP)

(72) Inventors: KENJI FUKUZONO, Kawasaki (JP); Yuki Hoshino, Kawasaki (JP)

(21) Appl. No.: 14/690,567

(22) Filed: Apr. 20, 2015

(30) Foreign Application Priority Data
Jun. 6, 2014 (JP) 2014-117614

(51) Int. Cl. H05K 7/20; G06F 1/20

(52) U.S. Cl. CPC H05K 7/20272; G06F 1/20

(57) ABSTRACT

A liquid-cooled jacket, includes: a cooling chamber including a first inner surface that extends along a to-be-cooled surface of an exothermic component; a heat transfer portion arranged in the cooling chamber and configured to transfer heat from the first inner surface to a second inner surface of the cooling chamber formed to oppose the first inner surface; an inflow path for a refrigerant including one end having an opening at a central portion of the second inner surface; a plurality of outflow holes for the refrigerant arranged in the second inner surface; and an outflow path, formed at a back side of an edge of the second inner surface, through which the refrigerant from the respective outflow holes circulates.

### CROSS-REFERENCE TO RELATED APPLICATION

This application is based upon and claims the benefit of priority from the prior Japanese Patent Application No. 2014-117614 filed on Jun. 6, 2014, the entire contents of which are incorporated herein by reference.

### FIELD

The embodiments discussed herein are related to a liquid-cooled jacket and an electronic device.

### BACKGROUND

Heating values of electronic components mounted in electronic devices such as computers are increased as the speed and functionality of the electronic components are highly increased.

Related technologies are disclosed in, for example, Japanese Laid-Open Patent Publication No. H08-227953, Japanese Laid-Open Patent Publication No. 2006-54351, Japanese Laid-Open Patent Publication No. 2009-194038, Japanese Laid-Open Patent Publication No. H08-241943, and Japanese Laid-Open Patent Publication No. 2004-6811.

### SUMMARY

According to one aspect of the embodiments, a liquid-cooled jacket, includes: a cooling chamber including a first inner surface that extends along a to-be-cooled surface of an exothermic component; a heat transfer portion arranged in the cooling chamber and configured to transfer heat from the first inner surface to a second inner surface of the cooling chamber formed to oppose the first inner surface; an inflow path for a refrigerant including one end having an opening at a central portion of the second inner surface; a plurality of outflow holes for the refrigerant arranged in the second inner surface; and an outflow path, formed at a back side of an edge of the second inner surface, through which the refrigerant from the respective outflow holes circulates.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 illustrates an example of a liquid-cooled jacket;

FIG. 2 illustrates an example of an internal structure of the liquid-cooled jacket;

FIG. 3 illustrates an example of a top plan view of the liquid-cooled jacket;

FIGS. 4 and 5 illustrate an example of a cross-sectional view of the liquid-cooled jacket;

FIG. 6 illustrates an example of an internal structure of the liquid-cooled jacket;

FIG. 7 illustrates an example of a flow of refrigerant in the liquid-cooled jacket;

FIG. 8 illustrates an example of a comparing result of pressure losses;

FIG. 9 illustrates an example of a comparing result of maximum temperatures of a component;

FIG. 10 illustrates an example of a temperature difference between a maximum temperature and a minimum temperature for a to-be-cooled surface;

FIG. 11 illustrates an example of an isothermal diagram of temperature distribution for the surface to-be-cooled;

FIG. 12 illustrates an example of the component of the liquid-cooled jacket; and

FIG. 13 illustrates an example of a process of forming the liquid-cooled jacket.

### DESCRIPTION OF EMBODIMENTS

The temperature of refrigerant that passes through a flow path formed along the to-be-cooled surface of an exothermic component, is slowly increased as the refrigerant flows from an upstream side toward a downstream side of the flow path. For this reason, cooling performance is relatively lower at the downstream side of the flow path through which the refrigerant passes than at the upstream side of the flow path.

A plurality of inflow paths is formed toward the to-be-cooled surface of the exothermic component, and a plurality of outflow paths is formed to oppose an inflow direction of the inflow path, such that the surface to-be-cooled may be uniformly cooled. A heat transfer area in the flow path with which the refrigerant is in contact may be enlarged as the inflow paths and the outflow paths formed to oppose the to-be-cooled surface are miniaturized. As the inflow path and the outflow path are miniaturized, a pressure loss is increased, and as a result, a flow rate of refrigerant may be decreased.

Even though the flow path formed to oppose the to-be-cooled surface of the exothermic component is miniaturized, a liquid-cooled jacket and an electronic device that reduce a pressure loss may be provided.

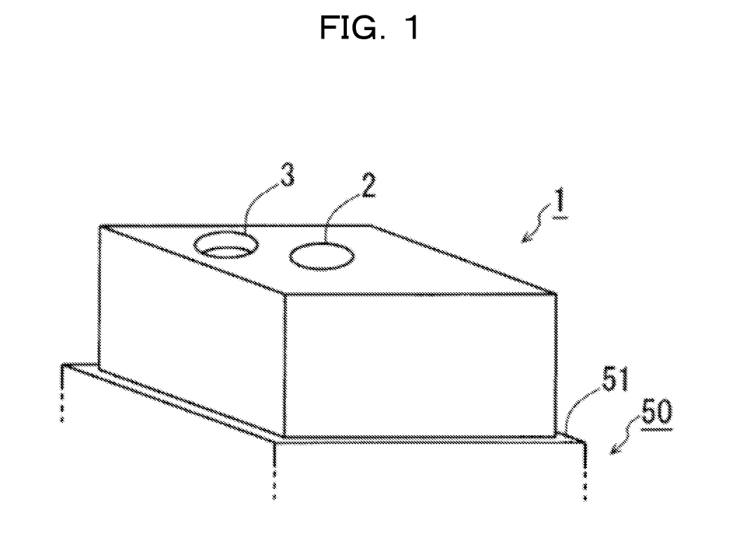

FIG. 1 illustrates an example of a liquid-cooled jacket. A liquid-cooled jacket 1 may be embedded in an electronic device in a state where the liquid-cooled jackets 1 are fixed to the to-be-cooled surfaces 51 of various types of exothermic components 50. For example, various types of thermal adhesives such as paste-type or solid-type thermal adhesives may be inserted between the to-be-cooled surface 51 and the liquid-cooled jacket 1.

The liquid-cooled jacket 1 has a refrigerant inlet 2 into which the refrigerant flows, and a refrigerant outlet 3 from which the refrigerant flows out. The liquid-cooled jacket 1 may allow the refrigerant to circulate in the interior of the liquid-cooled jacket 1 using piping or a pump that is coupled to the refrigerant inlet 2 and the refrigerant outlet 3.

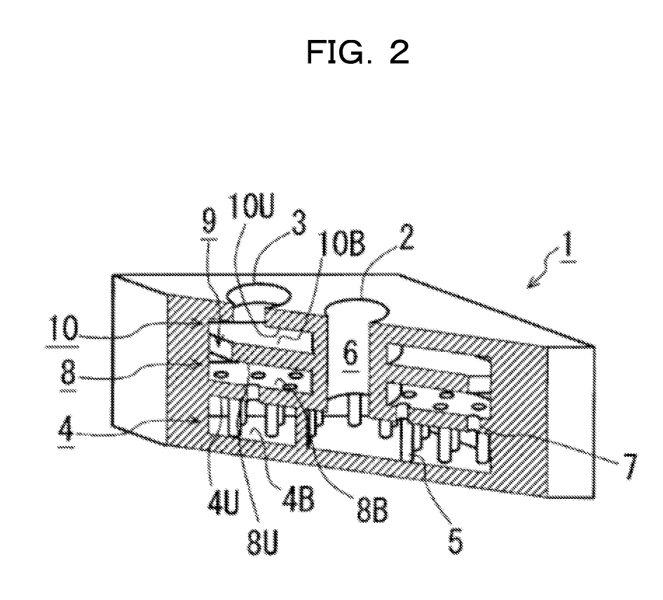

FIG. 2 illustrates an example of an internal structure of a liquid-cooled jacket. The liquid-cooled jacket illustrated in FIG. 2 may be the liquid-cooled jacket illustrated in FIG. 1. As illustrated in FIG. 2, the liquid-cooled jacket 1 has a cooling chamber 4 in which the refrigerant for cooling the component 50 circulates. The cooling chamber 4 has a bottom surface 4B that extends along the surface 51 of the to-be-cooled component 50. In FIG. 2, the cooling chamber 4, which has a rectangular shape of the bottom surface 4B that corresponds to a rectangular shape of the to-be-cooled surface 51, is illustrated, but the cooling chamber 4 may have any shape. The cooling chamber 4 may have a bottom surface having a shape that is suitable for a shape of the to-be-cooled surface of the component that is an object to be cooled.

Among inner surfaces that form the cooling chamber, the bottom surface is a surface that extends along the to-be-cooled surface of the component, and may not be in parallel with the ground surface. For example, in a case in which the liquid-cooled jacket is fixed to the to-be-cooled surface that is not in parallel with the ground surface, the bottom surface is not in parallel with the ground surface.

The liquid-cooled jacket 1 has heat transfer portions 5 which are arranged in the cooling chamber 4, and transfers the heat from the bottom surface 4B of the cooling chamber 4 to an upper surface 4U that is formed to oppose the bottom surface 4B. The heat transfer portions 5 may include thermally conductive columns that are arranged between the bottom surface 4B and the upper surface 4U of the cooling chamber 4. However, the heat transfer portions 5 are not limited to a specific type as long as the heat transfer portions 5 can transfer heat from the bottom surface 4B of the cooling chamber 4 to the upper surface 4U. For example, the heat transfer portion 5 may include a thermally conductive wall that is radially widened from a central portion of the cooling chamber 4.

The liquid-cooled jacket 1 has an inflow path 6 for the refrigerant having one end that is opened at the upper surface 4U of the cooling chamber 4. The refrigerant flowing in from the refrigerant inlet 2 circulates through the inflow path 6. The inflow path 6 couples the refrigerant inlet 2 and the cooling chamber 4 in a relatively short distance. For example, in a case where the upper surface 4U of the cooling chamber 4 is quadrangular, a portion, where diagonal lines of the upper surface 4U intersect, is a central portion of the upper surface 4U, but the inflow path 6 may be positioned at any position. The inflow path 6 may be positioned at a position where uniform cooling of the o-be-cooled surface t 51 may be expected, and for example, the inflow path 6 may not be aligned with the portion where the diagonal lines of the upper surface 4U intersect.

The liquid-cooled jacket 1 has a plurality of outflow hole 7 for the refrigerant arranged in the upper surface 4U of the cooling chamber 4. The number of outflow holes 7 or the sizes of the outflow holes 7 may be appropriately determined based on, for example, a cooling capability required to cool the component 50, the pump for circulating the refrigerant, and the liquid property of the refrigerant. In FIG. 2, the outflow holes 7 are arranged in the upper surface 4U of the cooling chamber 4 in longitudinal and lateral directions, but the outflow holes 7 may be arbitrarily arranged. For example, the outflow holes 7 may be arranged with an inclination or randomly in the upper surface 4U of the cooling chamber 4.

The liquid-cooled jacket 1 has a merging chamber 8 where the refrigerants passing through the respective outflow holes 7 merge together. The merging chamber 8 is formed at a back side of the upper surface 4U of the cooling chamber 4. The merging chamber 8 is formed between a bottom surface 8B in which the respective outflow holes 7 arranged in the upper surface 4U of the cooling chamber 4 are opened and an upper surface 8U that is disposed to oppose the bottom surface 8B. The liquid-cooled jacket 1 has an outflow path 9 through that the refrigerant, which has passed through the respective outflow holes 7, circulates. The outflow path 9 is formed at a back side at an edge of the upper surface 4U of the cooling chamber 4. The outflow path 9 may be a path that guides the refrigerant from a gap provided along an edge of the upper surface 8U of the merging chamber 8 toward a back side of the upper surface 8U. The liquid-cooled jacket 1 may have the merging chamber 8. For example, the liquid-cooled jacket 1 may have separate flow paths that connect the respective outflow holes 7 and the outflow path 9, respectively.

The liquid-cooled jacket 1 has a liquid chamber 10 into which the refrigerant, which has passed through the outflow path 9, flows. The liquid chamber 10 is formed at a back side of the upper surface 8U of the merging chamber 8. The liquid chamber 10 is formed between a bottom surface 10B where an opening of the outflow path 9 is formed along an edge thereof and an upper surface 10U in which an opening of the refrigerant outlet 3 is formed.

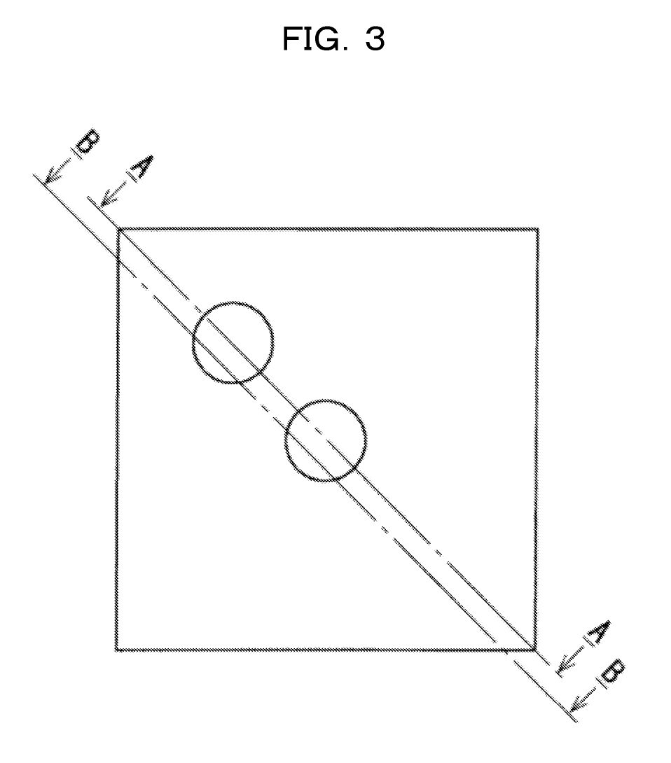

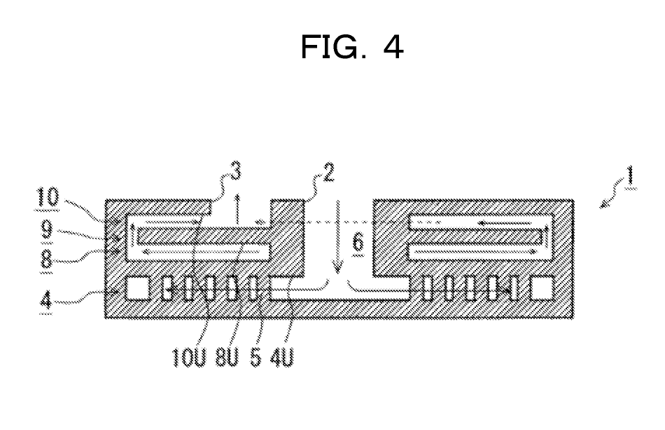

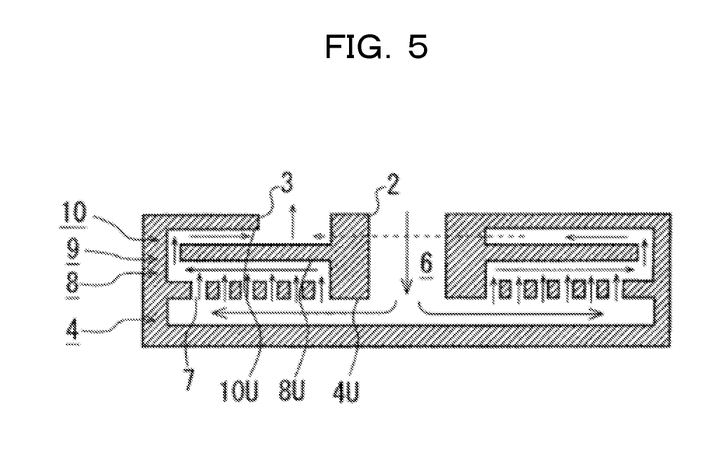

FIG. 3 illustrates an example of a top plan view of a liquid-cooled jacket. FIGS. 4 and 5 illustrate an example of a cross-sectional view of the liquid-cooled jacket. FIG. 4 illustrates a cross-sectional view of the liquid-cooled jacket 1 taken along the line A-A of FIG. 3. FIG. 5 illustrates a cross-sectional view of the liquid-cooled jacket 1 taken along the line B-B of FIG. 3. The arrows illustrated in FIGS. 4 and 5 indicate the flow of refrigerant.

The refrigerant, which has flowed from the refrigerant inlet 2 into the liquid-cooled jacket 1, passes through the inflow path 6. The refrigerant, which has passed through the inflow path 6, flows into the central portion in the cooling chamber 4. The inflow path 6 is positioned at the central portion of the upper surface 4U of the cooling chamber 4, and as a result, the refrigerant flows into the central portion of the cooling chamber 4 intensively. The refrigerant, which has flowed into the central portion of the cooling chamber 4, spreads throughout the interior of the cooling chamber 4. The refrigerant, which has spread in the cooling chamber 4, passes through the respective outflow holes 7 arranged in the upper surface 4U of the cooling chamber 4, and then flows out from the cooling chamber 4. The refrigerants, which have passed through the respective outflow holes 7, merge together in the merging chamber 8. The refrigerant, which has merged in the merging chamber 8, passes through the outflow path 9 provided at the edge of the upper surface 8U of the merging chamber 8, and then flows out from the merging chamber 8. The refrigerant, which has passed through the outflow path 9, flows into the liquid chamber 10. The refrigerant, has flowed into the liquid chamber 10, flows out from the liquid chamber 10 through the opening of the refrigerant outlet 3 formed in the upper surface 10U of the liquid chamber 10.

In the liquid-cooled jacket 1, since the refrigerant, which has passed through the inflow path 6 spreads throughout the interior of the cooling chamber 4 from the central portion of the cooling chamber 4, temperature distribution of the refrigerant may not be fluctuated in the cooling chamber 4. For this reason, any portion of the bottom surface 4B of the cooling chamber 4 is generally and uniformly cooled by the refrigerant. The to-be-cooled surface 51 of the component 50 may be generally and uniformly cooled.

In the liquid-cooled jacket 1, since the heat transfer portions 5 are formed in the cooling chamber 4, a heat transfer area in the cooling chamber 4 in contact with the refrigerant is larger than that in a case where there is no heat transfer portion 5. For this reason, the heat from the component 50 may be efficiently transferred to the refrigerant in the liquid-cooled jacket 1. In the liquid-cooled jacket 1, when the refrigerant passes through the fine outflow holes 7 arranged in the upper surface 4U of the cooling chamber 4, the heat from the upper surface 4U of the cooling chamber 4 is removed by the refrigerant. Since the heat from the bottom surface 4B of the cooling chamber 4 has been transferred to the upper surface 4U through the heat transfer portions 5, the component 50 may be efficiently cooled in comparison with a case where no heat is transferred from the bottom surface 4B to the upper surface 4U by the heat transfer portions 5.

The central portion of the to-be-cooled surface 51 of the component 50 is likely to be at a high temperature as compared to the edge of the to-be-cooled surface 51. In the liquid-cooled jacket 1, the refrigerant, which has passed through the outflow holes 7, passes through the outflow path 9 formed at the edge of the upper surface 8U of the merging chamber 8. For this reason, a phenomenon in which the central portion of the surface 51 of the component 50 to-be-cooled is at a high temperature may be decreased as compared with a case where the refrigerant, which has passed through the outflow holes 7, flows out from the vicinity of the central portion of the upper surface 8U of the merging chamber 8.

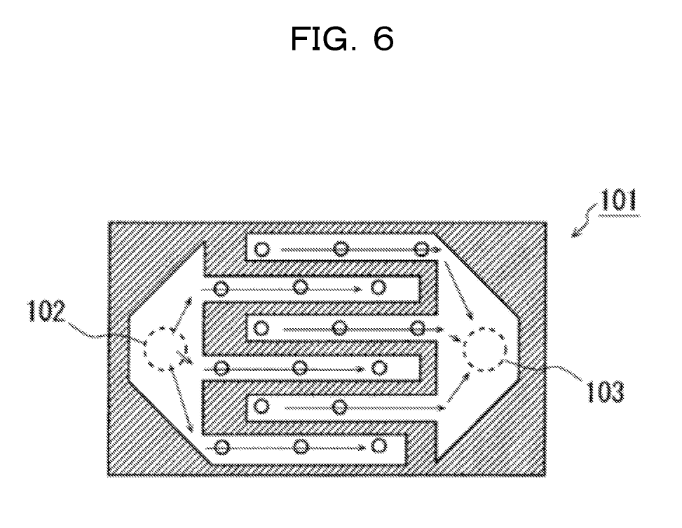

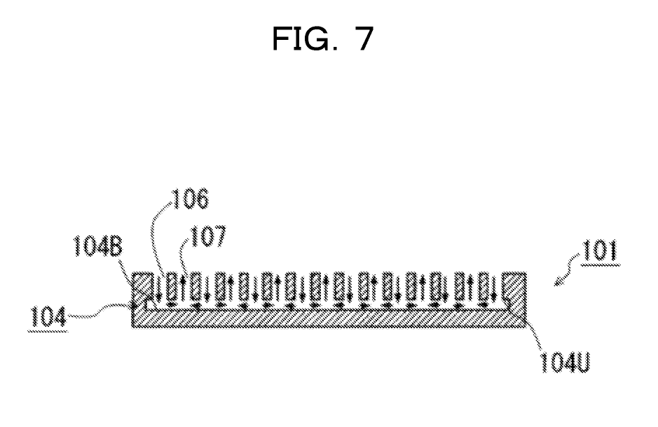

FIG. 6 illustrates an example of an internal structure of a liquid-cooled jacket. FIG. 7 illustrates an example of a flow of a refrigerant in a liquid-cooled jacket.

A cooling chamber 104, which has a bottom surface 104B that extends along the surface 51 of the to-be-cooled component 50, is provided in a liquid-cooled jacket 101 illustrated in FIG. 6. The refrigerant flowing from a refrigerant inlet 102 of the liquid-cooled jacket 101 circulates in the cooling chamber 104. The refrigerant, which has passed through the cooling chamber 104, flows out from a refrigerant outlet 103 of the liquid-cooled jacket 101. A plurality of inflow holes 106 through which the refrigerant flows into the cooling chamber 104 and a plurality of outflow holes 107 through which the refrigerant flows out from the cooling chamber 104 are arranged in an upper surface 104U of the cooling chamber 104 of the liquid-cooled jacket 101 as illustrated in FIG. 6. For example, in the liquid-cooled jacket 101 illustrated in FIG. 6, a plurality of inflow paths is formed toward the to-be-cooled surface 51 of the exothermic component 50, a plurality of outflow paths is formed to oppose an inflow direction of the inflow path, and the inflow paths and the outflow paths are miniaturized such that the heat transfer areas in the flow paths which are in contact with the refrigerant are enlarged.

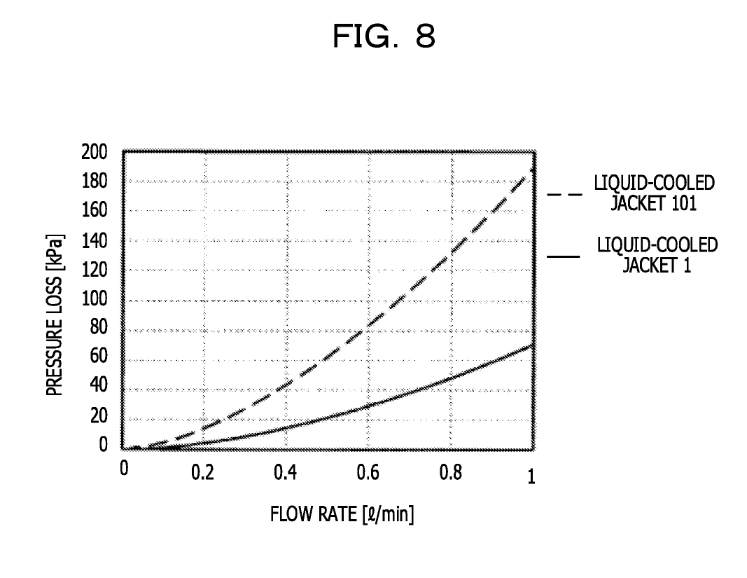

The liquid-cooled jacket 1 illustrated in FIG. 2 and the liquid-cooled jacket 101 illustrated in FIG. 6 are compared in terms of a pressure loss or a cooling performance when the component 50 is cooled using the same pump in a case where it is assumed that the heat generation density of the to-be-cooled surface 51 is 150 W/cm². FIG. 8 illustrates an example of a comparing result of pressure losses. For example, when the flow rate is 0.1 L/min, a pressure loss is decreased by about 80% in the liquid-cooled jacket 1 illustrated in FIG. 2 in comparison with the liquid-cooled jacket 101 as illustrated in FIG. 6. When the pressure loss is decreased, the flow rate of the refrigerant is increased, and as a result, an amount of heat transport of the refrigerant is increased.

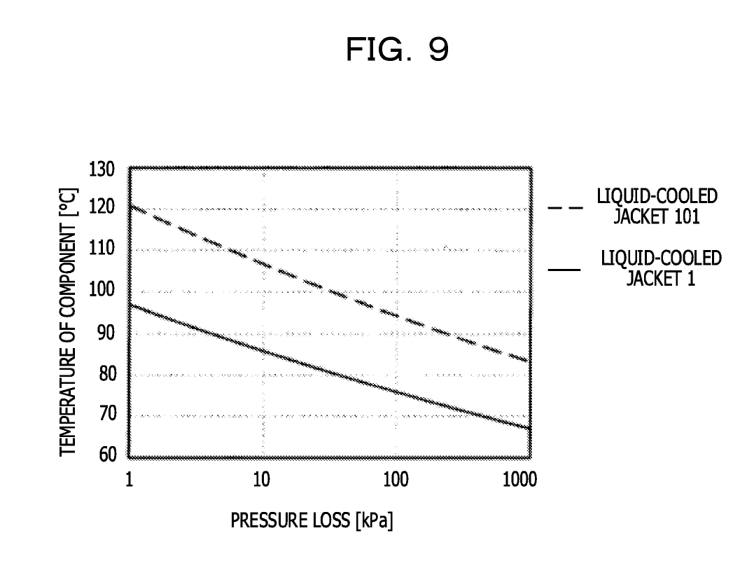

FIG. 9 illustrates an example of a comparing result of maximum temperatures of a component. For example, when a pressure loss is 10 kPa, a maximum temperature of the component 50 is decreased by about 10% in the liquid-cooled jacket 1 as illustrated in FIG. 2 in comparison with the liquid-cooled jacket 101 as illustrated in FIG. 6. In the liquid-cooled jacket 1 illustrated in FIG. 2, although the pressure loss is decreased, a heat transfer area in the liquid-cooled jacket 1 in contact with the refrigerant is increased such that a maximum temperature of the component 50 is decreased. When the cooling performance is improved by increasing the heat transfer area by miniaturizing the flow paths in the liquid-cooled jacket, an increase in the heat transfer area and a decrease in the pressure loss may be compatible with each other in the liquid-cooled jacket 1 as illustrated in FIG. 2 regardless of the existence of a trade-off relationship in which cooling performance deteriorates due to an increase in the pressure loss in the flow paths.

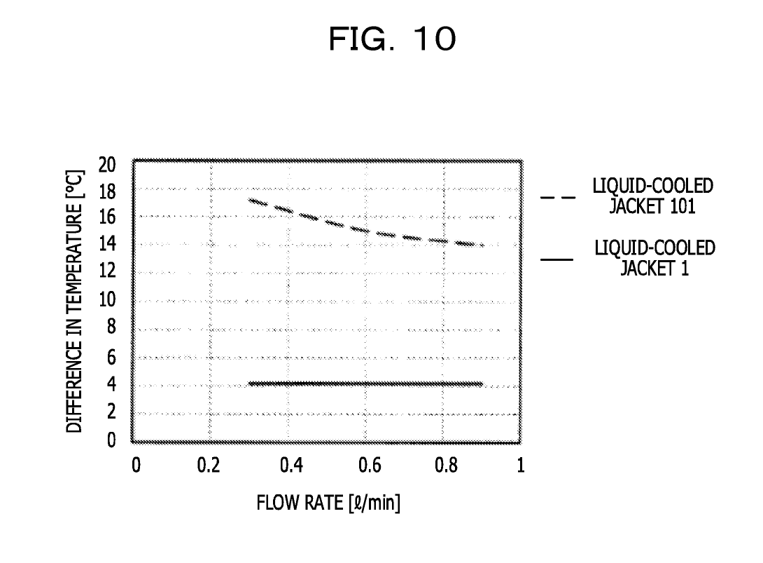

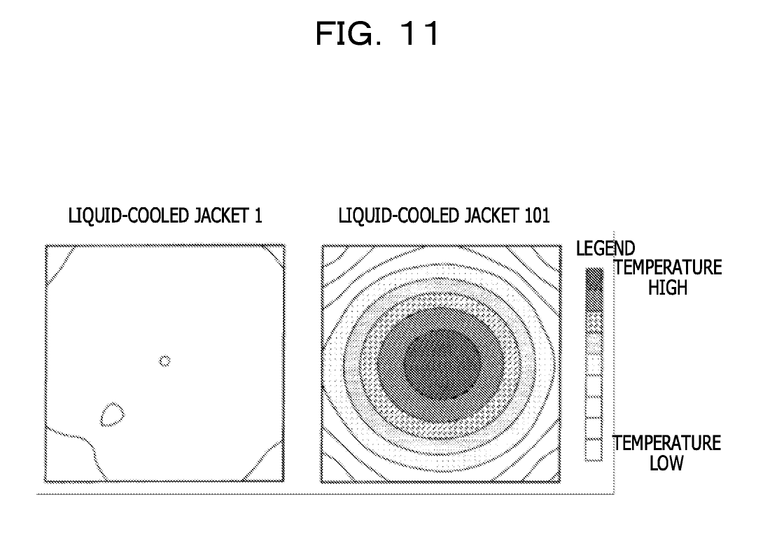

FIG. 10 illustrates an example of a difference in temperature between a maximum temperature and a minimum temperature in a to-be-cooled surface. A temperature difference between the maximum temperature and the minimum temperature in the to-be-cooled surface 51 is small in the liquid-cooled jacket 1 as illustrated in FIG. 2 as compared with the liquid-cooled jacket 101 as illustrated in FIG. 6. Although the flow rate of the refrigerant is changed, the temperature difference between the maximum temperature and the minimum temperature in the to-be-cooled surface 51 is difficult to be changed in the liquid-cooled jacket 1 as illustrated in FIG. 2 as compared with the liquid-cooled jacket 101 as illustrated in FIG. 6. FIG. 11 illustrates an example of an isothermal diagram of temperature distribution in a to-be-cooled the surface. FIG. 11 illustrates a temperature distribution when the flow rate of the refrigerant is 0.3 L/min. A temperature fluctuation distribution in the to-be-cooled surface 51 is small in the liquid-cooled jacket 1 as illustrated in FIG. 2 in comparison with the liquid-cooled jacket 101 as illustrated in FIG. 6.

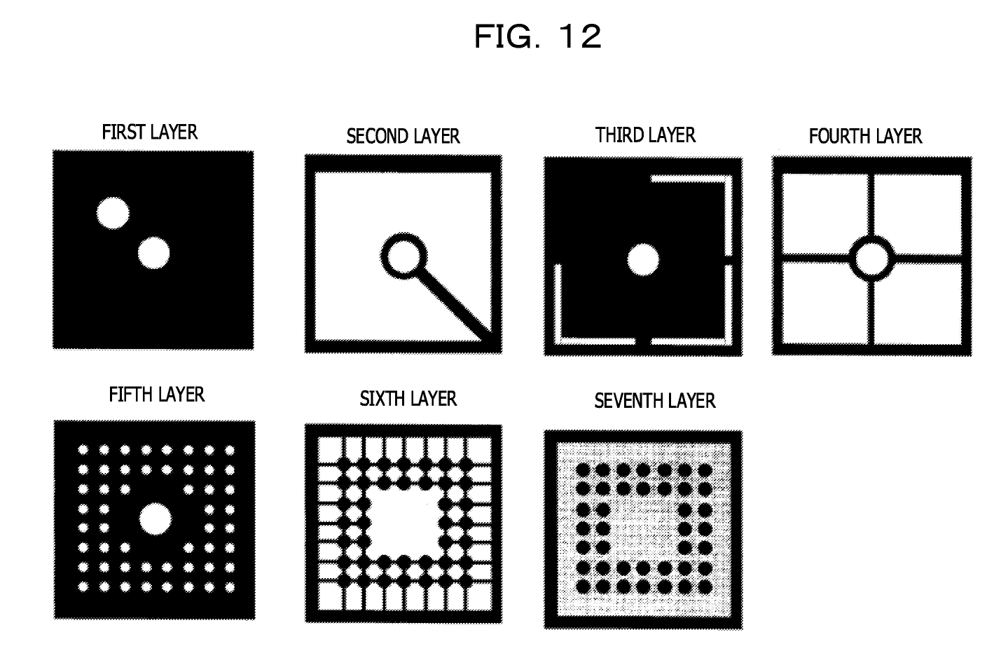

FIG. 12 illustrates an example of a component of the liquid-cooled jacket. For example, the liquid-cooled jacket 1 may have a laminated body with a seven-layered structure. For example, in a case where an uppermost portion of the liquid-cooled jacket 1 is a first layer and a lowermost portion is a seventh layer, the components having seven types of shapes illustrated in FIG. 12 may be used as members for the respective layers of the liquid-cooled jacket 1. For example, the first layer may be a member which forms the upper surface 10U of the liquid chamber 10 or a plate-shaped member which has the refrigerant inlet 2 and the refrigerant outlet 3. A second layer may be a plate-shaped member that forms a wall surface of the liquid chamber 10 or a part of the inflow path 6. A third layer may be a plate-shaped member that forms the bottom surface 10B of the liquid chamber 10, the upper surface 8U of the merging chamber 8, a part of the inflow path 6, or the outflow path 9. A fourth layer may be a plate-shaped member that forms a wall surface of the merging chamber 8 or a part of the inflow path 6. A fifth layer may be a plate-shaped member that forms the bottom surface 8B of the merging chamber 8, the upper surface 4U of the cooling chamber 4, the outflow hole 7, and a part of the inflow path 6. A sixth layer may be a plate-shaped member that forms the heat transfer portions 5 or a wall surface of the cooling chamber 4. The seventh layer may be a plate-shaped member that forms the bottom surface 4B of the cooling chamber 4 or the heat transfer portions 5. The first to sixth layers may be formed by appropriately using an etching technology such as a double-sided etching or other processing technologies. The seventh layer may be formed by appropriately using a half etching method or other processing technologies.

In the third layer illustrated in FIG. 12, the outflow path 9 may not be formed along the entire circumference of the edge of the upper surface 8U of the merging chamber 8. In order to allow the flow rate of the refrigerant passing through the respective portions of the outflow path 9 to be uniform, the outflow path 9 may be formed in an area where is at the back side of an edge of the upper surface 8U and is other than the vicinity of the refrigerant outlet 3. The outflow path 9 may be formed along the entire circumference of the edge of the upper surface 8U of the merging chamber 8.

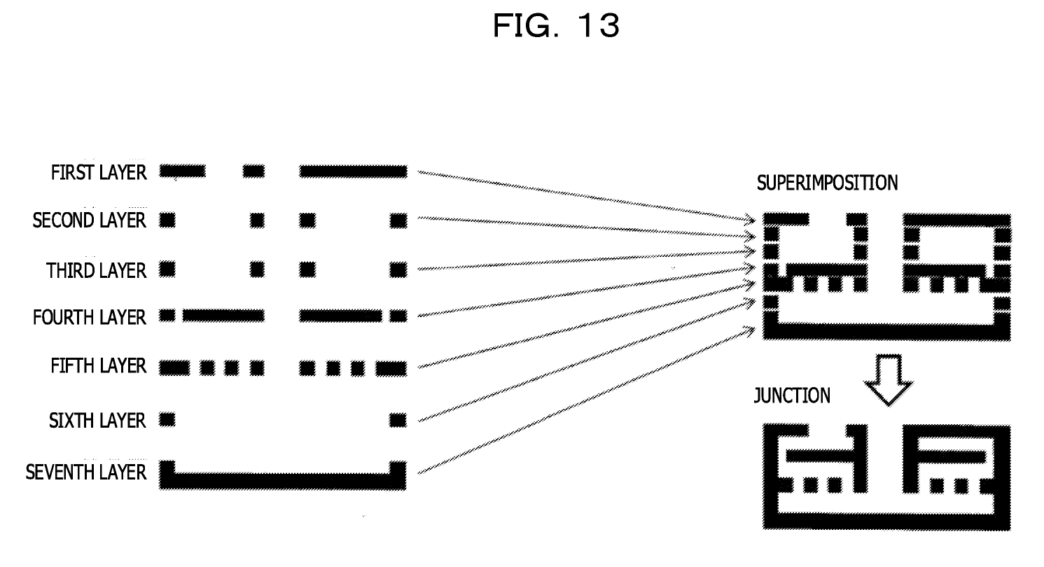

FIG. 13 illustrates an example of a process of forming a liquid-cooled jacket. For example, in FIG. 13, the respective layers from the first layer to the seventh layer are joined together to form the liquid-cooled jacket 1. For example, when the respective layers from the first layer to the seventh layer are superimposed and joined together, the liquid-cooled jacket 1 illustrated in FIG. 2 is manufactured. For example, when the respective layers are joined together, a junction technology such as a soldering or a diffused junction may be applied. For example, the respective layers from the first layer to the seventh layer are superimposed and joined together such that the liquid-cooled jacket 1 having the cooling chamber 4 or the heat transfer portions 5, the inflow path 6, the outflow hole 7, and the outflow path 9, is formed.

In a semiconductor device such as a central processing unit (CPU), as an example of the component 50 that may be cooled by the liquid-cooled jacket 1, a heating value is increased proportionally as the performance of the semiconductor device is increased. For this reason, a high performance is desirable for a technology of cooling the CPU. For example, a forced air cooling technology using a high-performance heat sink may be used to cool the CPU as long as the heating value thereof is about 35 W/cm². Because the heating value of the CPU exceeds 50 W/cm², and may exceed 60 W/cm² later, a water cooling technology, which exhibits more excellent cooling performance than the air cooling technology, is expected to be utilized. In a special electronic device such as a supercomputer, it is possible to use cold water which circulates in the existing cooling device that is installed in a facility in which machinery is to be installed. Since no cooling device capable of cooling an electronic device using water is available in an office or at home, the cooling device may be provided in the electronic device in an office or at home in order to cool the electronic device using water. In the electronic device installed in an office or at home, a circulating water cooling method may be applied in which the water cooling technology and the air cooling technology are combined. In the case of the circulating water cooling method which removes the heat generated from the CPU using the liquid-cooled jacket, and uses a circulation path of the refrigerant which is cooled by air using a radiator, the refrigerant is circulated using, for example, a pump. For this reason, an efficient structure may be desirable which reduces a resistance that obstructs a flow of the refrigerant that circulates along the flow path and has small thermal resistance of the liquid-cooled jacket or the radiator. Because the liquid-cooled jacket is disposed close to an exothermic element such as the CPU, the structure of the liquid-cooled jacket greatly affects the cooling performance as compared with other components. For example, even compared with the liquid-cooled jacket 101 illustrated in FIG. 6, the liquid-cooled jacket 1 illustrated in FIG. 2 has an excellent characteristic in terms of a pressure loss or a cooling performance such that the exothermic element such as the CPU may be efficiently cooled.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A liquid-cooled jacket, comprising:
a cooling chamber including a first inner surface that extends along a to-be-cooled surface of an exothermic component;
a heat transfer portion arranged in the cooling chamber and configured to transfer heat from the first inner surface to a second inner surface of the cooling chamber formed to oppose the first inner surface;
an inflow path for a refrigerant including one end having an opening at a central portion of the second inner surface;
a plurality of outflow holes for the refrigerant arranged in the second inner surface; and
an outflow path, formed at a back side of an edge of the second inner surface, through which the refrigerant from the respective outflow holes circulates.

2. The liquid-cooled jacket according to claim 1, wherein the heat transfer portions include a thermally conductive column that is arranged between the first inner surface and the second inner surface.

3. The liquid-cooled jacket according to claim 1, further comprising:
a merging chamber formed at a back side of the second inner surface and including a third inner surface on which each of the plurality of outflow holes opens,
wherein the refrigerants from each of the plurality of outflow holes merge together.

4. The liquid-cooled jacket according to claim 3, wherein the outflow path guides the refrigerant from a gap provided along an edge of a fourth inner surface that is formed to oppose the third inner surface in the merging chamber, toward a back side of the fourth inner surface.

5. The liquid-cooled jacket according to claim 1, further comprising:
a refrigerant outlet through which the refrigerant flows out from the liquid-cooled jacket.

6. The liquid-cooled jacket according to claim 5, wherein the outflow path is formed in an area where is at a back side of an edge of the second inner surface and is other than the vicinity of the refrigerant outlet.

7. An electronic device having a liquid-cooled jacket, the liquid-cooled jacket comprising:
an exothermic component;
a cooling chamber including a first inner surface that extends along a to-be-cooled surface of the exothermic component;
a heat transfer portion arranged in the cooling chamber configured to transfer heat from the first inner surface to a second inner surface of the cooling chamber formed to oppose the first inner surface;
an inflow path for a refrigerant including one end having an opening at a central portion of the second inner surface;
a plurality of outflow holes for the refrigerant arranged in the second inner surface; and
an outflow path, formed at a back side of an edge of the second inner surface, through which the refrigerant from each of the plurality of outflow holes circulates.

8. The electronic device according to claim 7, wherein the heat transfer portions include a thermally conductive column that is arranged between the first inner surface and the second inner surface.

9. The electronic device according to claim 7, further comprising:
a merging chamber formed at a back side of the second inner surface and including a third inner surface on which each of the plurality of outflow holes opens,
wherein the refrigerants from each of the plurality of outflow holes merge together.

10. The electronic device according to claim 9, wherein the outflow path guides the refrigerant from a gap provided along an edge of a fourth inner surface that is formed to oppose the third inner surface in the merging chamber, toward a back side of the fourth inner surface.

11. The electronic device according to claim 7, further comprising:
a refrigerant outlet through which the refrigerant flows out from the liquid-cooled jacket.

12. The electronic device according to claim 11, wherein the outflow path is formed in an area where is at a back side of an edge of the second inner surface and is other than the vicinity of the refrigerant outlet.
